(19) United States
(12) Patent Application Publication
(10) Pub. No.: US 2009/0034196 A1
(43) Pub. Date: Feb. 5, 2009

(54) HEAT-DISSIPATING MODULE

(75) Inventors: Feng-Ku Wang, Taipei City (TW); Chih-Kai Yang, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/850,480

(22) Filed: Sep. 5, 2007

(30) Foreign Application Priority Data
Jul. 30, 2007 (TW) 96127748

(51) Int. Cl. H05K 7/20

(52) U.S. Cl. 361/702; 361/697

(57) ABSTRACT

A heat-dissipating module adapted for cooling a heat-generating element is provided. The heat-dissipating module includes a fin module, a fan and a heat pipe. The fan is adapted for generating an air current. The fin module includes a plurality of first fins and a plurality of second fins. Each first fin includes a first edge facing the fan. The first edges are located on a first surface. Each second fin includes a second edge facing the fan. The second edges are located on a second surface not coinciding with the first surface. The air current passes through the first surface and the second surface and then passes by the first fins and the second fins. The heat pipe includes a first end thermally coupled to the heat-generating element, and a second end thermally coupled to the first fins and the second fins.

### CROSS-REFERENCE TO RELATED APPLICATION

This application claims the priority benefit of Taiwan application serial no. 96127748, filed on Jul. 30, 2007. All disclosure of the Taiwan application is incorporated herein by reference.

### BACKGROUND OF THE INVENTION

1. Field of the Invention

The present invention relates to a heat-dissipating module, and more particularly, to a heat-dissipating module with fins.

2. Description of Related Art

With rapid advance of computer technology in recent years, computers are made to operate at higher frequency, and a heat generation rate of each of electronic elements in a computer host has become greater and greater. To avoid temporary or permanent failure of the electronic elements in the computer host due to overheat, dissipating the heat generated by the electronic elements in the computer host is of critical importance.

Taking a central processing unit (CPU) as an example, when the temperature of the CPU itself exceeds its normal operating temperature during operation at high frequency, operation errors or temporary failures of the CPU will probably occur, resulting in a crash of the computer host. In addition, when the temperature of the CPU itself is much higher than its normal operating temperature, transistors in the CPU will be probably damaged, resulting in the permanent failure of the CPU.

FIG. 1A is a three-dimensional exploded view of a conventional heat-dissipating module, and FIG. 1B is a three-dimensional assembled view of the heat-dissipating module of FIG. 1A. As shown in FIGS. 1A and 1B, the conventional heat-dissipating module 100 is adapted for cooling a heat-generating element 10. The heat-dissipating module 100 includes a fin module 110, a fan 120, a heat pipe 130, a casing 140 and a heat-conducting element 150. The fin module 110 includes a plurality of fins 114. Each fin 114 has an edge 114a and each edge 114a facing the fan 120 is straight. The edges 114a of the fins 114 are located on a plane 112. The fan 120 is disposed in an accommodating space 142 of the casing 140 and adjacent to the plane 112.

An outlet 144 of the casing 140 corresponds to the plane 112 in such a manner that an air current 122 generated by the fan 120 may flow through the outlet 144 and the plane 112 and then into a clearance 116 formed between each two adjacent fins 114. In addition, the heat pipe 130 includes a first end 132 and a second end 134. The first end 132 is thermally coupled to the heat-generating element 10 through the heat-conducting element 150, and the second end 134 passing through the fins 114 is thermally coupled to the fins 114.

With the development of the computers toward miniaturization, the room for the heat-dissipating module 100 is becoming smaller and smaller. However, a minimum distance between the fan 120 and the plane 112 must be maintained to be larger than a predetermined value, or the turbulence occurring at the plane 112 becomes even worse to increase the noise during operation of the fan 120. Therefore, to meet the requirements of the miniaturization of the heat-dissipating module 100 without increasing the noise, the conventional solution is to reduce the size of the fan 120 or reduce the length 114b of each fin 114. However, any of the above solutions may degrade the heat-dissipating capacity of the heat-dissipating module 100.

### SUMMARY OF THE INVENTION

The present invention is directed to a heat-dissipating module with low noise and good heat-dissipating capacity.

The present invention provides a heat-dissipating module adapted for cooling a heat-generating element. The heat-dissipating module comprises a fin module, a fan and a heat pipe. The fan is adapted for generating an air current. The fin module comprises a plurality of first fins and a plurality of second fins. Each of the first fins has a first edge facing the fan. The first edges are located on a first surface. Each of the second fins has a second edge facing the fan. The second edges are located on a second surface not coinciding with the first surface. The air current passes through the first surface and the second surface and then passes by the first fins and the second fins. A first end of the heat pipe is thermally coupled to the heat-generating element, and a second end of the heat pipe is thermally coupled to the first fins and the second fins.

According to an embodiment of the present invention, each of the first edges may have a regular shape. In addition, each of the first edges may have a straight shape, an arc shape, a serrated shape, or a wavy shape.

According to an embodiment of the present invention, each of the second edges may have a regular shape. In addition, each of the first edges may have a straight shape, an arc shape, a serrated shape, or a wavy shape.

According to an embodiment of the present invention, the heat-dissipating module further comprises a heat-conducting element thermally coupled to the heat-generating element. The first end of the heat pipe is thermally coupled to the heat-conducting element.

According to an embodiment of the present invention, the heat-dissipating module further comprises a casing having an accommodating space and an outlet. The fan is disposed in the accommodating space, the outlet corresponds to the first surface and the second surface, and the air current passes through the outlet.

According to an embodiment of the present invention, the second end of the heat pipe may pass through the first fins and the second fins.

According to an embodiment of the present invention, the second fins may be located between the first fins.

Since the first surface and the second surface don't coincide with each other, the air current may smoothly pass through the first surface and the second surface and then pass by the first fins and the second fins when the heat-dissipating module operates. In other words, as the heat-dissipating module of the present invention operates, turbulence occurring when the air current passes through the first surface and the second surface may be reduced, such that the noise resulted from the turbulence may be reduced.

In order to make the aforementioned and other features and advantages of the present invention more comprehensible, embodiments accompanied with figures are described in detail below.

### BRIEF DESCRIPTION OF THE DRAWINGS

FIG. 1A is a three-dimensional exploded view of a conventional heat-dissipating module.

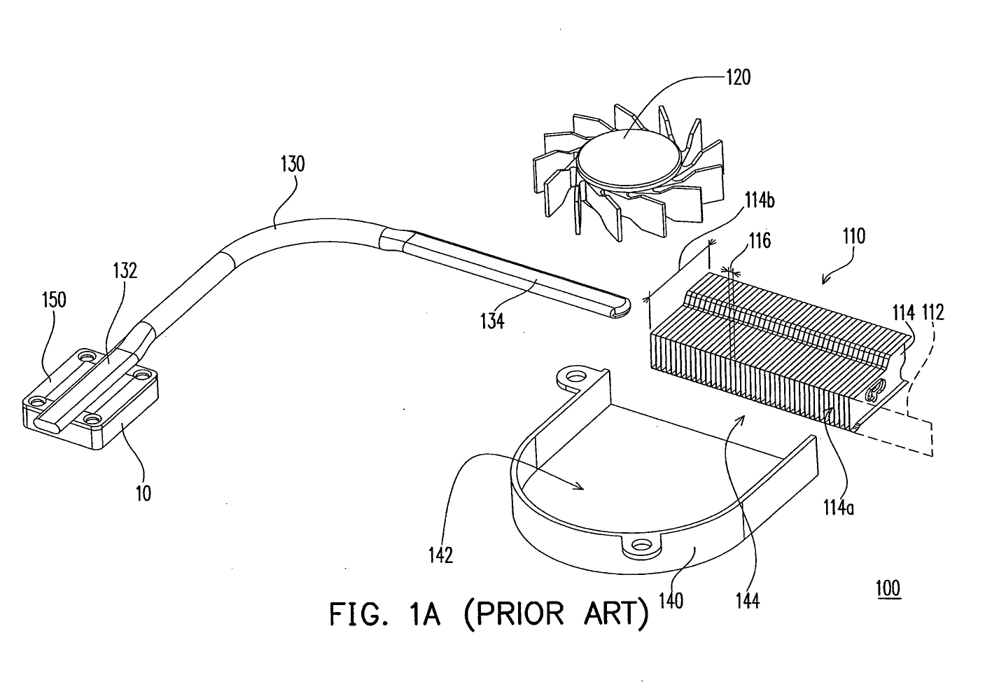

FIG. 1B is a three-dimensional assembled view of the heat-dissipating module of FIG. 1A.

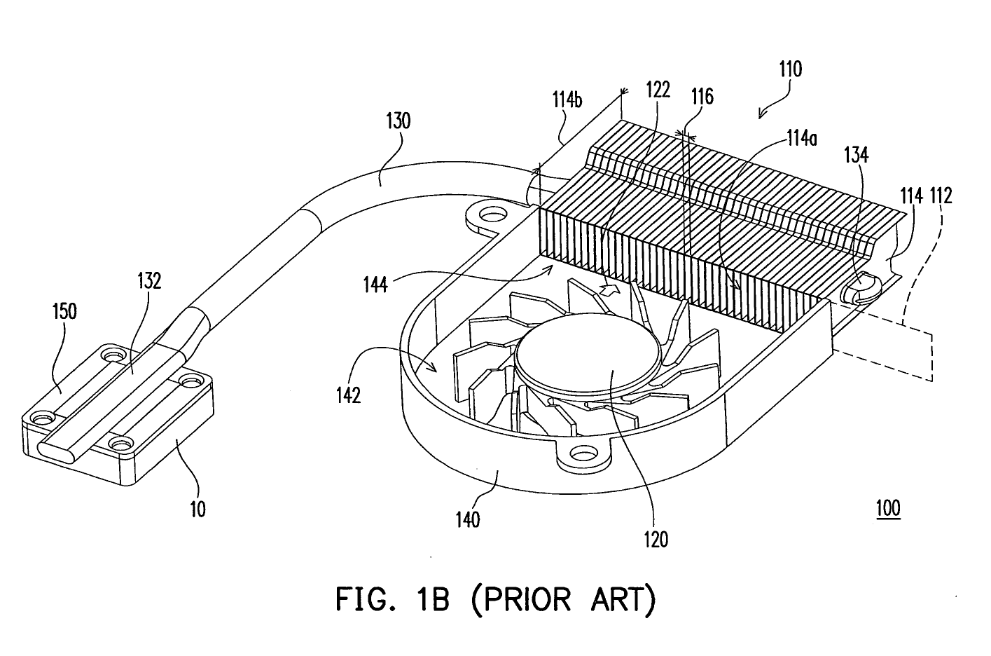

FIG. 2A is a three-dimensional exploded view of a heat-dissipating module in accordance with a first embodiment of the present invention.

FIG. 2B is a three-dimensional assembled view of the heat-dissipating module of FIG. 2A.

FIG. 3 is a three-dimensional exploded view of a heat-dissipating module in accordance with a second embodiment of the present invention.

FIG. 4 is a three-dimensional view of another fin module in accordance with the second embodiment of the present invention.

### DESCRIPTION OF THE EMBODIMENTS

### First Embodiment

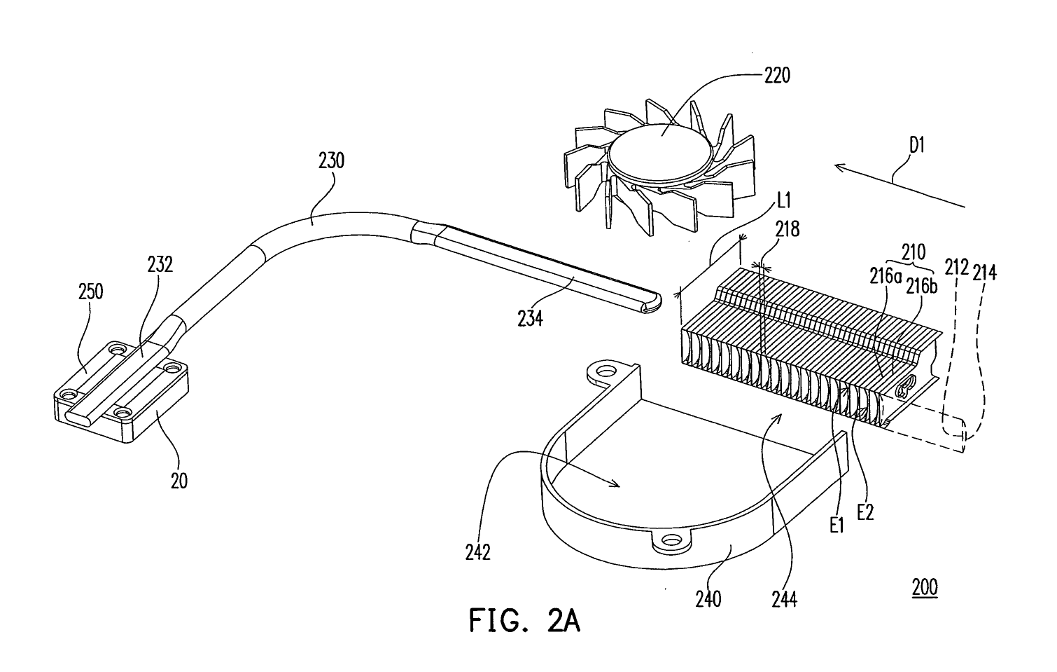

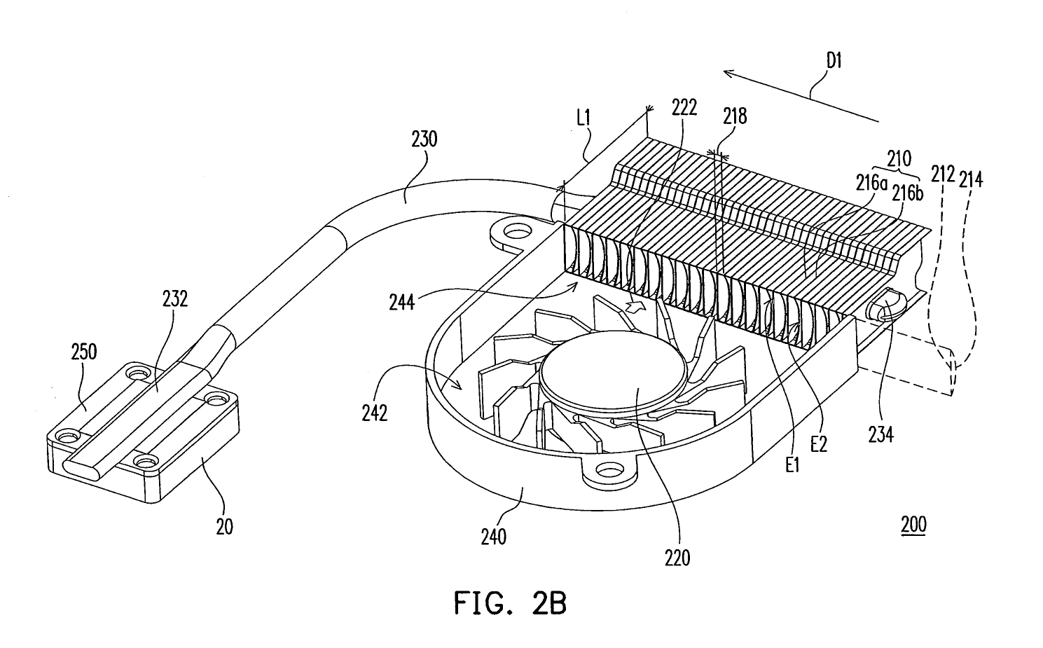

FIG. 2A is a three-dimensional exploded view of a heat-dissipating module in accordance with a first embodiment of the present invention, and FIG. 2B is a three-dimensional assembled view of the heat-dissipating module of FIG. 2A. It should be noted that, for the convenience of illustration, a first surface 212 and a second surface 214 of FIGS. 2A and 2B are shown to extend beyond the fin module 210 to clearly show positional relationship between the first surface 212 and the second surface 214.

Referring to FIGS. 2A and 2B, the heat-dissipating module 200 is adapted for cooling a heat-generating element 20. The heat-dissipating module 200 includes a fin module 210, a fan 220 and a heat pipe 230. The fin module 210 includes a plurality of first fins 216a and a plurality of second fins 216b. Each first fin 216a has a first edge E1 facing the fan 220, and the first edges E1 are located on a first surface 212. Each second fin 216b has a second edge E2 facing the fan 220, and the second edges E2 are located on a second surface 214 that does not coincide with the first surface 212.

In the present embodiment, the first fins 216a and the second fins 216b are alternately arranged. It should be understood that, however, the arrangement of the first fins 216a and the second fins 216b may be changed according to various design requirements. For example, the second fins 216b may be arranged between the first fins 216a in any manner. Alternatively, the second fins 216b may not be arranged between the first fins 216a.

The fan 220 may be disposed adjacent to the first surface 212 and is adapted for generating an air current 222. The air current 222 passes through the first surface 212 and the second surface 214, and then passes by the first fins 216a and the second fins 216b. In the present embodiment, the air current 222 first flows through the first surface 212 and the second surface 214 and then into a plurality of clearances 218, wherein each clearance 218 is formed between the corresponding first fin 216a and the corresponding neighboring second fin 216b. In addition, the heat pipe 230 includes a first end 232 and a second end 234. The first end 232 is thermally coupled to the heat-generating element 20, and the second end 234 may pass through the first fins 216a and the second fins 216b to be thermally coupled to the first fins 216a and the second fins 216b.

The development of electronic devices (e.g., computers) toward miniaturization results in the room being smaller and smaller for the heat-dissipating module 200, and the designer requires that a minimum distance between the fan 220 and the first surface 212 is kept to be larger than a predetermined value. Because the first surface 212 and the second surface 214 don't coincide with each other, the air current 222 may smoothly flow through the first surface 212 and the second surface 214 and then into the clearances 218 during operation of the heat-dissipating module 200. In other words, as the heat-dissipating module 200 of the present embodiment operates, turbulence occurring when the air current 222 passes through the first surface 212 and the second surface 214 may be reduced, such that the noise resulted from the turbulence may be reduced. In addition, unlike the conventional heat-dissipating module, it is unnecessary to reduce the size of the fan 220 of the heat-dissipating module 200 of the present embodiment and the length L1 of each first fin 216a of the heat-dissipating module 200 of the present embodiment and, therefore, the heat-dissipating capacity of the heat-dissipating module 200 of the present embodiment may be good.

In the present embodiment, each first edge E1 may have a regular shape and each second edge E2 may have a regular shape. Specifically, the first fins 216a and the second fins 216b are arranged in a direction D1 and the direction D1 is perpendicular to the maximum heat-dissipating surface of each first fin 216a and that of each second fin 216b. When viewed in the direction D1, each first edge E1 may have a straight shape and each second edge E2 may have an arc shape. In other words, the first surface 212 may be a plane, and the second surface 214 may be a cambered surface. However, each first edge E1 and each second edge E2 may have other shapes as described below according to various requirements.

In the present embodiment, the heat-dissipating module 200 further includes a casing 240 and a heat-conducting element 250. The casing 240 has an accommodating space 242 and an outlet 244. The fan 220 is disposed in the accommodating space 242, the outlet 244 corresponds to the first surface 212 and the second surface 214, and the air current 222 passes through the outlet 244. The heat-conducting element 250 is thermally coupled to the heat-generating element 20, and the first end 232 of the heat pipe 230 is thermally coupled to the heat-conducting element 250.

### Second Embodiment

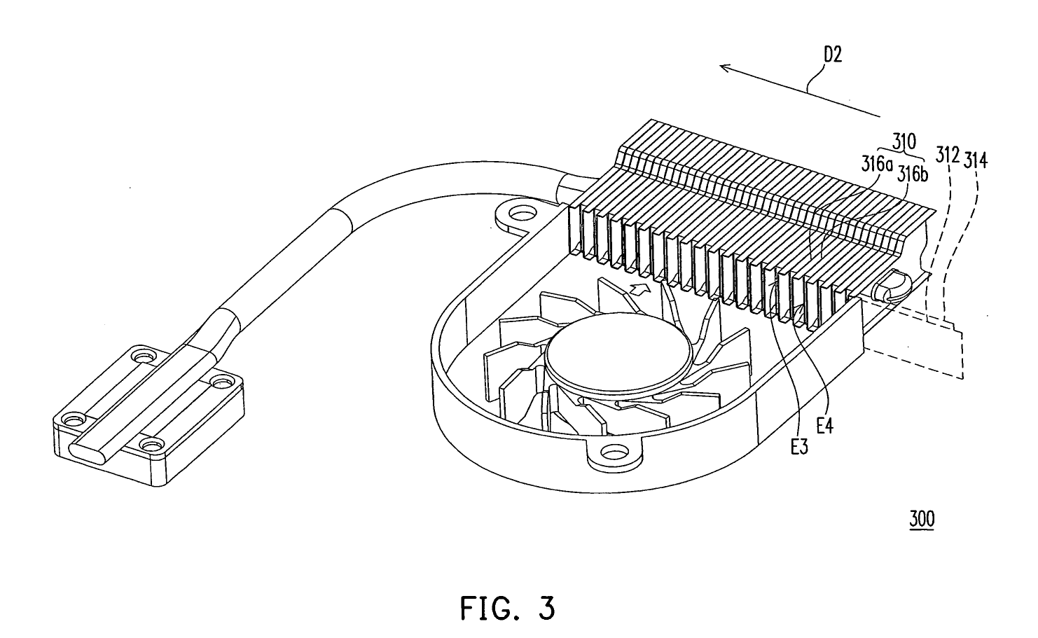

FIG. 3 is a three-dimensional exploded view of a heat-dissipating module in accordance with a second embodiment of the present invention. It should be noted that, for the convenience of illustration, a first surface 312 and a second surface 314 of FIG. 3 are shown to extend beyond a fin module 310 to clearly show positional relationship between the first surface 312 and the second surface 314.

Referring to FIG. 3, the heat-dissipating module 300 of the second embodiment is different from the heat-dissipating module 200 of the first embodiment in that each first fin 316a and each second fin 316b of the fin module 310 may be similar in shape. In the second embodiment, the first fins 316a and the second fins 316b are arranged in a direction D2 and the direction D2 is perpendicular to the maximum heat-dissipating surface of each first fin 316a and that of each second fin 316b. When viewed in the direction D2, each first edge E3 may have a straight shape and each second edge E4 may have a straight shape. In other words, a first surface 312 on which the first edges E3 are located may be a plane, and a second surface 314 on which the second edges E4 are located may be a plane. However, the first plane 312 is not coplanar with the second plane 314.

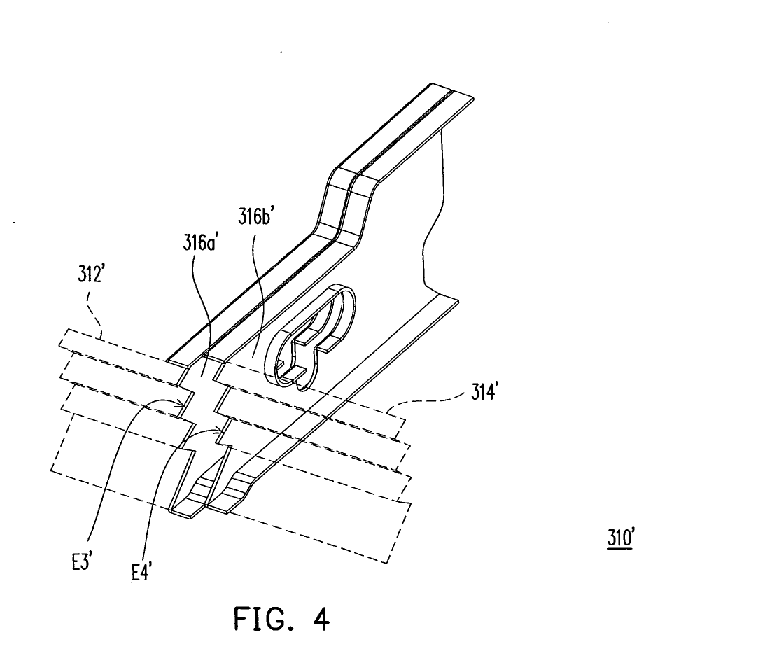

FIG. 4 is a three-dimensional view of another fin module in accordance with the second embodiment of the present invention. It should be noted that a first edge E3′ of each first fin 316a′ (one is schematically shown in FIG. 4) of the fin module 310′ may have a serrated shape or a wavy shape (not shown), and a second edge E4′ of each second fin 316b′ (one is schematically shown in FIG. 4) of the fin module 310′ may have a serrated shape or a wavy shape (not shown), depending upon the designer's requirements. In other words, a first surface 312′ on which the first edges E3′ are located may be a folded surface (i.e. corrugated surface), a second surface 314′ on which the second edges E4′ are located may be a folded surface (i.e. corrugated surface), and the first surface 312′ does not coincide with the second surface 314′.

In sum, the heat-dissipating module of the present invention has at least the following advantages:

1. Since the first surface and the second surface don't coincide with each other, the air current may smoothly pass through the first surface and the second surface and then pass by the first fins and the second fins when the heat-dissipating module operates. In other words, as the heat-dissipating module of the present invention operates, turbulence occurring when the air current passes through the first surface and the second surface may be reduced, such that the noise resulted from the turbulence may be reduced.

2. Unlike the conventional heat-dissipating module, it is unnecessary to reduce the size of the fan and the length of each first fin of the heat-dissipating module of the present invention and, therefore, the heat-dissipating capacity of the heat-dissipating module of the present invention may be good.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A heat-dissipating module adapted for cooling a heat-generating element, comprising:
a fan adapted for generating an air current;
a fin module, comprising:
a plurality of first fins, wherein each of the first fins has a first edge facing the fan, and each of the first fins has the same length, and the first edges are located on a first surface; and
a plurality of second fins, wherein each of the second fins has a second edge facing the fan, and each of the second fins has the same length, the second edges are located on a second surface not coinciding with the first surface; and
a heat pipe, wherein a first end of the heat pipe is thermally coupled to the heat-generating element, and a second end of the heat pipe is thermally coupled to the first fins and the second fins,
wherein the first fins and the second fins have equal lengths and are alternately arranged, and each of the first edges has an arc shape.

2-4. (canceled)

5. The heat-dissipating module of claim 1, wherein each of the second edges has a straight shape, an arc shape, a serrated shape, or a wavy shape.

6. (canceled)

7. The heat-dissipating module of claim 1, further comprising a casing having an accommodating space and an outlet, wherein the fan is disposed in the accommodating space, the outlet corresponds to the first surface and the second surface, and the air current passes through the outlet.

8. The heat-dissipating module of claim 1, wherein the second end of the heat pipe passes through the first fins and the second fins.

9. (canceled)

10. A heat-dissipating module adapted for cooling a heat-generating element, comprising:
a fan adapted for generating an air current;
a fin module, comprising:
a plurality of first fins, wherein each of the first fins has a first edge facing the fan, and each of the first fins has the same length, and the first edges are located on a first surface; and
a plurality of second fins, wherein each of the second fins has a second edge facing the fan, and each of the second fins has the same length, the second edges are located on a second surface not coinciding with the first surface; and
a heat pipe, wherein a first end of the heat pipe is thermally coupled to the heat-generating element, and a second end of the heat pipe is thermally coupled to the first fins and the second fins,
wherein the length of the first fins is larger than the length of the second fins, and the first fins and the second fins are alternately arranged, and the first edges have a serrated shape.

11. The heat-dissipating module of claim 10, wherein each of the second edges has an arc shape, a serrated shape, or a wavy shape.

12. The heat-dissipating module of claim 10, further comprising a casing having an accommodating space and an outlet, wherein the fan is disposed in the accommodating space, the outlet corresponds to the first surface and the second surface, and the air current passes through the outlet

13. The heat-dissipating module of claim 10, wherein the second end of the heat pipe passes through the first fins and the second fins.
